(19) United States
(12) Patent Application Publication
(10) Pub. No.: US 2024/0372022 A1
(43) Pub. Date: Nov. 7, 2024

(54) Flexible and Rollable Solar Panels Having an Integrated Functional Backing Layer of Polymeric Foam

(71) Applicant: SOLARPAINT LTD., YOKNEAM ILLIT (IL)

(72) Inventors: Eran Maimon, Kibbutz Nahsholim (IL); Ramon Joseph Albalak, Haifa (IL)

(21) Appl. No.: 18/776,300

(22) Filed: Jul. 18, 2024

Related U.S. Application Data
(63) Continuation of application No. PCT/IL2023/050068, filed on Jan. 22, 2023.
Application No. PCT/IL2023/050068 is a continuation-in-part of application No. PCT/IL2022/050339, filed on Mar. 29, 2022.
(63) Continuation-in-part of application No. 18/635,039, filed on Apr. 15, 2024.
Application No. 18/635,039 is a continuation of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
(63) Continuation-in-part of application No. 18/372,720, filed on Sep. 26, 2023.
Application No. 18/372,720 is a continuation of application No. PCT/IL2022/050339, filed on Mar. 29, 2022.
Application No. PCT/IL2022/050339 is a continuation-in-part of application No. PCT/IL2021/051202, filed on Mar. 30, 2021.
Application No. PCT/IL2021/051202 is a continuation-in-part of application No. PCT/IL2021/051269, filed on Oct. 27, 2021.
Application No. PCT/IL2021/051269 is a continuation-in-part of application No. PCT/IL2022/050030, filed on Jan. 10, 2022.
Application No. PCT/IL2022/050030 is a continuation-in-part of application No. 17/353,867, filed on Jun. 22, 2021, now Pat. No. 11,978,815.
Application No. 18/372,720 is a continuation-in-part of application No. 17/353,867, filed on Jun. 22, 2021, now Pat. No. 11,978,815.
Application No. PCT/IL2022/050030 is a continuation-in-part of application No. 17/802,335, filed on Aug. 25, 2022, now abandoned.
Application No. 18/372,720 is a continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/372,720 is a continuation-in-part of application No. 18/136,359, filed on Apr. 19, 2023.
Application No. 18/136,359 is a continuation of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
Application No. 18/372,720 is a continuation-in-part of application No. 17/802,335, filed on Aug. 25, 2022, now abandoned.
Application No. 17/802,335 is a continuation-in-part of application No. 18/217,620, filed on Jul. 3, 2023.
Application No. 18/217,620 is a continuation of application No. PCT/IL2022/050030, filed on Jan. 10, 2022.
(60) Provisional application No. 63/302,159, filed on Jan. 24, 2022.
(60) Provisional application No. 63/167,660, filed on Mar. 30, 2021.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.
(60) Provisional application No. 63/088,535, filed on Oct. 7, 2020.
(60) Provisional application No. 63/106,666, filed on Oct. 28, 2020.

(51) Int. Cl. H01L 31/0445; H01L 31/0224; H01L 31/18

(52) U.S. Cl. CPC H01L 31/0445; H01L 31/022458; H01L 31/186

(57) ABSTRACT

A photovoltaic article, that is configured to generate electricity from light, includes: a flexible and rollable and non-brittle solar cell, that is capable of being flexed and being rolled without becoming broken or non-operational; and an integrated, functional, backing layer that is non-detachably attached to a back side of that flexible and rollable and non-brittle solar cell. The backing layer is formed of foamed polymer, and can be flexible and rollable while also providing mechanical support to the solar cell.

### CROSS-REFERENCE TO RELATED APPLICATIONS

This patent application is a Continuation of PCT international patent application number PCT/IL2023/050068, having an international filing date of Jan. 22, 2023, which is hereby incorporated by reference in its entirety.

The above-mentioned PCT/IL2023/050068 claims priority and benefit from U.S. 63/302,159, filed on Jan. 24, 2022, which is hereby incorporated by reference in its entirety.

The above-mentioned PCT/IL2023/050068 is also a Continuation-in-Part (CIP) of, and claims benefit and/or priority from, PCT international patent application number PCT/IL2022/050339, having an international filing date of Mar. 29, 2022, which is hereby incorporated by reference in its entirety; which claims benefit and priority from U.S. 63/167,660, filed on Mar. 30, 2021, which is hereby incorporated by reference in its entirety.

This patent application is also a Continuation-in-Part (CIP) of U.S. Ser. No. 18/635,039, filed on Apr. 15, 2024, which is hereby incorporated by reference in its entirety.

The above-mentioned U.S. Ser. No. 18/635,039 is a Continuation of U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety; which claims priority and benefit (I) from U.S. Ser. No. 16/362,665, filed on Mar. 24, 2019, now U.S. Pat. No. 11,081,606 (issued on Aug. 3, 2021), which is hereby incorporated by reference in its entirety, and (II) from U.S. 62/785,282, filed on Dec. 27, 2018, which is hereby incorporated by reference in its entirety.

This patent application is also a Continuation-in-Part (CIP) of U.S. Ser. No. 18/372,720, filed on Sep. 26, 2023, which is hereby incorporated by reference in its entirety.

The above-mentioned U.S. Ser. No. 18/372,720 is also a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from patent application U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 18/372,720 is also a Continuation-in-Part (CIP) of U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit (I) from U.S. Ser. No. 16/362,665, filed on Mar. 24, 2019, now U.S. Pat. No. 11,081,606 (issued on Aug. 3, 2021), which is hereby incorporated by reference in its entirety, and (II) from U.S. 62/785,282, filed on Dec. 27, 2018, which is hereby incorporated by reference in its entirety.

The above-mentioned PCT/IL2022/050030 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

The above-mentioned U.S. Ser. No. 18/372,720 is also a Continuation-in-Part (CIP) of U.S. Ser. No. 18/129,865, filed on Apr. 2, 2023, which is hereby incorporated by reference in its entirety. The above-mentioned U.S. Ser. No. 18/129,865 is a Continuation of PCT international patent application number PCT/IL2021/051202, having an international filing date of Oct. 7, 2021, which is hereby incorporated by reference in its entirety. The above-mentioned PCT/IL2021/051202 claims priority and benefit from (i) U.S. 63/088,535, filed on Oct. 7, 2020, which is hereby incorporated by reference in its entirety; and from (ii) U.S. Ser. No. 17/353,867, filed on Jun. 22, 2021, now patent number U.S. Pat. No. 11,978,815 (issued on May 7, 2024), which is hereby incorporated by reference in its entirety.

The above-mentioned U.S. Ser. No. 18/372,720 is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 18/372,720 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

The above-mentioned U.S. Ser. No. 18/372,720 is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide a flexible and rollable solar panel that has an integrated functional backing layer of polymeric foam (or polymeric foam substrate, or foamed substrate); as well as methods and systems for producing or manufacturing such solar panel.

For example, a foamed polymeric backing layer, or a foamed polymeric substrate layer, is attached or glued or bonded or laminated or heat-pressed, to or beneath or adjacent to a flexible and rollable sollar cell (or, to a flexible and rollable sheet or strip or matrix or array of a plurality of solar cells); for example, beneath (or adjacent to) an integral backsheet of such solar cell and in addition to such integral backsheet (that is formed of other, non-foamed and/or non-polymeric material). The foamed polymeric backing layer provides additional or increased mechanical support and/or mechanical protection and/or mechanical resilience to the solar cell; and/or reduces the overall density (or, the overall Specific Weight) of the integrated PV article to enable it (or to assist it) to float on water or to float in a body-of-water or to otherwise improve its buoyancy. Some embodiments may provide other and/or additional benefits and/or advantages.

### BRIEF DESCRIPTION OF THE DRAWINGS

FIG. 1 is a schematic illustration of a cross-sectional view of a PV solar panel having a functional foamed backing layer, in accordance with some demonstrative embodiments.

FIG. 2 is a schematic illustration of a system for manufacturing PV solar cells or PV solar panels having a functional polymeric foam-based backing layer, in accordance with some demonstrative embodiments.

### DETAILED DESCRIPTION OF SOME DEMONSTRATIVE EMBODIMENTS

The Applicants have realized that some conventional solar panels are typically rigid, heavy, cumbersome, brittle and/or fragile units, that are typically installed on roofs or in other locations (e.g., a solar energy park, a solar energy farm, a solar power plant).

The Applicants have realized that it may be beneficial to produce and to utilize a solar panel that is flexible and rollable (e.g., can be rolled and later un-rolled, substantially without breaking, or substantially without becoming non-functional, or without substantial reduction in operational efficiency, or without any reduction in operational efficiency), and is also thin and light-weight; and which may optionally float on water (e.g., in a natural or artificial body of water, ocean, sea, lake, river, pool, water reservoir, or the like).

Some embodiments provide photovoltaic solar cells having a functional backing layer made of polymeric foam of a foamed substrate or a polymeric foam substrate; as well as methods and systems for producing such solar cells. In accordance with some embodiments, the solar cell is flexible and rollable, and is non-brittle and non-fragile; and maintains all or most of its PV functionality even after being rolled and un-rolled, and does not break and does not become damaged or non-operational or broken upon rolling or un-rolling. Some embodiments further provide methods, systems, and tooling for producing or manufacturing such PV solar cells or solar panels, having such functional polymeric foam backing layer.

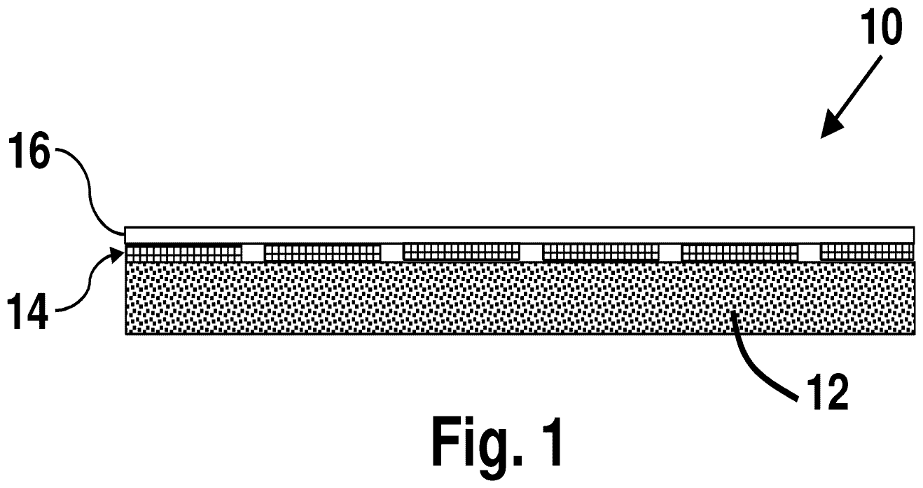

Reference is made to FIG. 1, which is a schematic illustration of a cross-sectional view of a PV solar panel 10 having a functional foamed (or foam-based, or foamed-polymer) backing layer, in accordance with some demonstrative embodiments. The PV solar panel 10 includes a plurality of neighboring solar cells 14, which may be touching each other or may be spaced-apart from each other; optionally arranged in a structure of rows and/or columns, or in a structure of an array or a matrix, or as another structure or group. In some embodiments, each of solar cells 14 is by itself a flexible and rollable and non-brittle solar cell.

In some embodiments, solar cells 14 are encapsulated between layers on an encapsulant, such as: one or more Polyolefin Elastomer (POE) layers or encapsulants, Thermoplastic Polyolefin (TPO) layers or encapsulants, Ethylene-Vinyl Acetate (EVA) layers or encapsulants, Polyethylene Ethylene-Vinyl Acetate (PEVA), layers or encapsulants, or a combination of two or more such types of layers or encapsulants. The plurality of solar cells 14 are backed with (or mounted on, or attached to) a backsheet film or a back-sheet film (or layer, or foil); for example, made of a fluoro-polymer (e.g., a fluorocarbon-based polymer having multiple carbon-fluorine bonds), polyvinylidene fluoride (PVDF), poly-ethylenetetra-fluoroethylene (ETFE), poly-ethylene-chlorotrifluoro-ethylene (ECTFE), or a combination or a stacking of two or more such materials.

In accordance with some embodiments, the above-described structure is backed with (or is mounted on, or is attached onto) a functional polymeric foam-based backing layer 12, that is a polymer foam or that is foamed polymer or that is a foam-based polymer or that is polymeric foam, or other polymer-based material that has bubbles or air-bubbles scattered therein or trapped therein, or other polymer-based material that has cavities or caves or tunnels in which air may reside. The Applicants have realized that such polymeric foam or foamed polymer may be utilized as a functional backing layer for such structure of flexible and rollable solar cells; to leverage the mechanical and/or physical and/or other properties of such polymeric foamed functional backing layer, for example, light weight, impact resistance, mechanical forces absorption and/or dissipation, thermal insulation, and/or restraining properties.

In some embodiments, the functional polymeric foam-based backing layer 12 is formed as a structure having exclusively closed cells, and no open cells; such that substantially all the foam cells are closed; and such type of polymeric foam-based backing layer 12 may be suitable for implementations in which a more rigid or less flexible support layer is desired, and/or if it is desired to prevent entrance of liquids or moisture into such foamed cells. As another non-limiting example, the functional polymeric foam-based backing layer 12 is formed as a structure having exclusively (or mostly, or dominantly) closed cells in order to provide improved floating or buoyancy properties, operating as a floating means to enable the mounted solar cells to be placed onto a body-of-water and to float thereon.

In other embodiments, the functional polymeric foam-based backing layer 12 is formed as a structure having exclusively open cells, and no closed cells; such that substantially all the foam cells are at least partially open; and such type of polymeric foam-based backing layer 12 may be suitable for implementations in which increased flexibility or increased elastic properties are desired. As another non-limiting example, the functional polymeric foam-based backing layer 12 is formed as a structure having exclusively (or mostly, or dominantly) open cells for utilization as a support base for solar cells placed onto a roof of a house.

In other embodiments, the functional polymeric foam-based backing layer 12 is formed as a structure having both closed foam cells and open foam cells, in accordance with a pre-defined ratio (e.g., ratio of 50:50, or ration of 60:40), or in accordance with a pre-defined range of ratio (e.g., a range of ratios from 20:80 to 30:70), in order to achieve a particular level of flexibility or rigidity.

In other embodiments, the functional polymeric foam-based backing layer 12 is formed as a structure having one or more distinct regions formed exclusively of closed foam cells, and further having one or more other distinct regions formed exclusively of open foam cells; for example, in accordance with a pre-defined pattern or arrangement or structure. For example, edges or borders or margins or a frame of the functional polymeric foam-based backing layer 12 are formed of closed foam cells (to provide increased rigidity to such edges or borders or margins or frame), wherein inner or central region(s) of the functional polymeric foam-based backing layer 12 are formed of open foam cells (to provide increased flexibility to such inner or central region(s)). In other embodiments, edges or borders or margins or a frame of the functional polymeric foam-based backing layer 12 are formed of open foam cells (to provide increased flexibility to such edges or borders or margins or frame), wherein inner or central region(s) of the functional polymeric foam-based backing layer 12 are formed of closed foam cells (to provide increased rigidity to such inner or central region(s)). In other embodiments, an alternating pattern or a chessboard pattern or regions may be used, alternating between region(s) of closed foam cells and regions of open foam cells. Other suitable structures may be used.

In some embodiments, the functional polymeric foam-based backing layer 12 is formed of (or includes, or consists of) one or more thermoplastic foams selected from a group consisting of: foamed polypropylene, foamed polyethylene, foamed polystyrene, foamed polyolefin, foamed polylactic acid, a combination of two or more of said materials, or one or more other thermoplastic foams.

In some embodiments, the functional polymeric foam-based backing layer 12 is implemented as a full layer that is provided adjacent as a full or different backing layer that further supports the solar cells 14. In other embodiments, the functional polymeric foam-based backing layer 12 is implemented as a partial layer or as particular regions or zones within (or adjacent to) other type of backing layer or support layer; and the functional polymeric foam-based backing layer 12 may optionally be structured as straight lines, curved lines, zig-zag structure, dots or circles, polygon regions or polygon zones, or other suitable structure of combination of structures; for example, in order to meet particular desired properties (e.g., flexibility level, rigidity levels, flexible zones or regions, rigid zones or regions, or the like).

In some embodiments, the functional polymeric foam-based backing layer 12 may be fortified with, or reinforced by, or may be mounted over or beneath, a scrim or a cloth or a gauze or a back-cloth or a fabric layer or a felt layer, or a soft or relatively soft metallic sheet or metallic foil, or a combination of two or more such layers.

In some embodiments, the functional polymeric foam-based backing layer 12 may further comprise one or more functional fillers or functional agents; for example, heat conducting fillers, heat absorbing fillers, heat dissipating fillers, ultraviolet (UV) protection fillers or UV radiation absorption layer, impact absorbing fillers, mechanical forces dissipation agents or fillers, mechanical forces absorption fillers or agents, fire retardant fillers or agents, fire-resistant fillers or agents, mechanical softening fillers, or a combination of two or more such agents or fillers. In some embodiments, such fillers or agents may be particularly placed only in one or more particular regions or zones of the functional polymeric foam-based backing layer 12 (e.g., only at the frame or borders or edges; or only at the center; or other regions), in order to provide particular functional properties to such particular regions or zones.

In some embodiments, the morphology of the functional polymeric foam-based backing layer 12 is configured or determined by using one or more additives or additive agents, such as nanoparticles or micro-particles or foaming agents, and/or particular types of soft (or rigid, or semi-rigid) granules or pellets; in order to achieve particular or desired functional properties, flexibility/rigidity properties, or the like.

In some embodiments, optionally, the encapsulated solar cells 14 may be covered by a front-sheet; for example, formed of a fluoro-polymer (e.g. PVDF, ETFE, ECTFE, or a combination of two or more such materials); or by a transparent or translucent or at least partially transparent front-sheet; or by other suitable front-sheet layers.

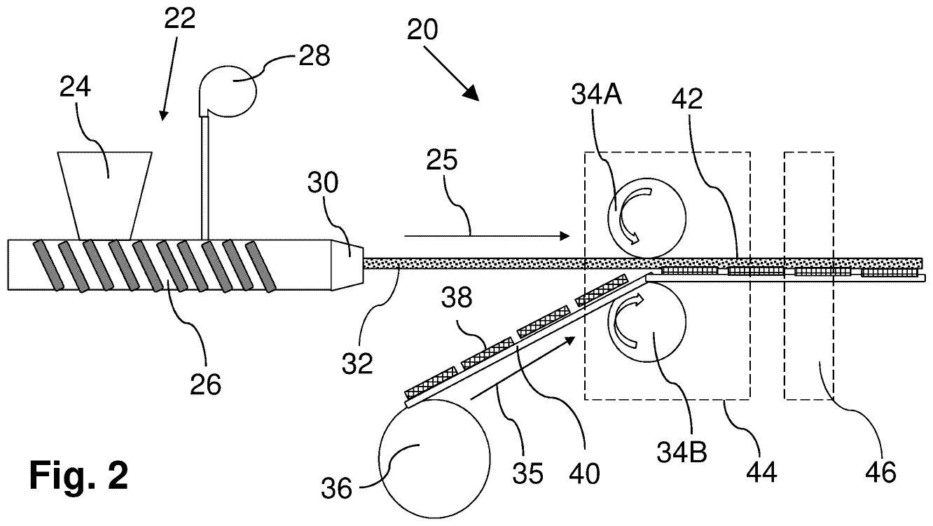

Reference is made to FIG. 2, which is a schematic illustration of a system 20 for manufacturing PV solar cells or PV solar panels having a functional polymeric foam-based backing layer, in accordance with some demonstrative embodiments. System 20 may comprise an extruder unit 22, for example, utilized in a continuous manufacturing process. Pellets or granules or particles or other objects of thermoplastic material and/or raw thermoplastic material and/or recycled thermoplastic material are inserted through a hopper 24 to a heated barrel 26, and are melted due to high temperature in the heated barrel 26. Gas 28 is injected within (or into) the barrel 26 and particularly into the polymer melt, to thereby form a foaming effect that causes formation of foam cells or foam bubbles. The polymer melt is extruded through an extrusion die 30, such as, in the shape or structure of a polymeric foamed melt sheet 32, or in the form of a polymeric foamed melt strip. In some embodiments, the polymeric foamed melt sheet (or strips) did not yet solidify at this stage, or is only semi solidified or partially solidified at this stage. It is noted that the polymer melt is extruded, as a foamed polymeric melt layer, directly onto (or beneath, or towards) the solar cells (or the sheet or array or strip of solar cells), or directly towards or beneath or adjacent to a rear-side of the backsheet of the solar cell, as an integral part of the production of the foamed polymeric layer, and as a singular production step that simultaneously (I) creates the foamed polymeric layer and (II) causes the currently-created foamed polymeric layer to be immediately attached to the rear side of the solar cell (or the sheet or matrix or strip of solar cells); and the foamed polymeric backing layer is Not produced as a separate or additional manufacturing step, in which firstly a foamed polymeric sheet is produced as a stand-alone sheet, and then such already-produced foamed sheet is glued to a rear side of a solar cell.

The polymeric foamed melt sheet (or strip) is advanced (e.g., using a conveyor belt or other robotic movement unit or automated movement unit), in the direction as indicated by arrow 25; towards a unit or a tooling that comprises two rollers 34A and 34B that roll or spin or rotate in opposite directions (e.g., one roller rolls clockwise; the other roller rolls counter-clockwise; as indicated by the curved arrows), so as to further forward the polymeric foamed melt sheet 32 therebetween. It is noted that system 20 may comprise other or additional units, which are not shown in order to not over-crowd the drawing; for example, conveyor belt, robotic arm(s), advancing film(s), heating unit(s), cooling unit(s), reservoir of raw materials, additional rollers or pushing units or advancing units or pulling units, mechanical support units, or the like.

A continuous batch or strip or roll or sheet of flexible PV solar cells is provided; for example, as a roll 36 of flexible and rollable PV solar cells 38; such as, rollable and non-brittle PV solar cells that may be provided as a roll or as a rolled strip or as a rolled sheet; or particularly, flexible and rollable solar cells that are singulated and/or that have increased mechanical resilience and/or increased capability to absorb and/or dissipate mechanical forces by having non-transcending gaps or craters or grooves that penetrated into between 50 percent to 99.9 percent (but not 100 percent) of the entire height (or depth) of the semiconductor wafer of such solar cells; with such non-transcending gaps or craters or grooves being (optionally) filled, partially or entirely, with a filler material that further assists in absorbing or dissipating mechanical forces; thereby providing a rollable and flexible and non-brittle solar cell (or series or array or matrix or sheet or strip of solar cells) that can be rolled and un-rolled without any damage or without significant damage to the functionality and/or efficiency of the solar cells.

The solar cells 38 are provided or moved onto a front-sheet 40, and are laminated or glued or mounted or attached onto (or beneath) such front-sheet 40; for example, such that the front-sheet 40 touches or laminates or covers the “sunny side” or the active side of the solar cells 38 (e.g., the side that is intended to be facing the sun or light-source for PV conversion of light to electricity). The flexible and rollable solar cells 38, as they are laminated onto or beneath the front-sheet 40 (or, in some embodiments, after such lamination; or, in some embodiments, before such lamination), are advancing forwardly in the direction indicated by arrow 35, adjacent to the front-sheet 40; and they enter between two rollers 34A and 34B of the tooling system, where the back side (or the “dark side”) of the flexible and rollable solar cells 38 is facing towards (or, is adjacent to) the polymeric sheet melt 32. The two rollers 34A and 34B, and/or (in some embodiments) other pressing unit(s) may be utilized, press together the polymeric sheet melt 32 and the flexible and rollable solar cells 38, in accordance with a pre-defined pressing level or pressure level, optionally also with heating that accompanies such pressing and assists in attaching the “dark side” of the flexible and rollable solar cells 38 to the polymeric sheet melt 32; and the pressed-together sheet 42 (or strip, or batch) then advanced from such tooling unit of system 20 as a functional PV solar cell sheet that is backed with a foamed polymeric melt. Optionally, the tooling unit and the solar cells with the polymeric foam melt (that were pressed together and became a singular sheet 42) move forward into or within an oven or a furnace or a heating unit 44 so as to keep the polymeric foam as a melt when it meets the solar cells sheet. The backsheet of the solar cell laminate may be pre-heated, to ensure or to facilitate adequate bonding or gluing or attachment of the solar cells to the polymer foam melt.

In some embodiments, the combined singular sheet 42 (formed of the solar cells that were attached to the polymeric foam melt) may be left to cool down, such as at room temperature. In other embodiments, optionally, the combined singular sheet 42 may be pushed or carried or routed into, or may pass through, a cooling sub-system 46 which provides a cooled environment. Upon its cooling down, the combined singular sheet 42 may optionally be rolled or wound or spun into a roll of solar cells that are integrally attached to the foamed polymeric backing layer or backing substrate, such as a generally cylindrical roll; or may be otherwise folded, packaged, transported, and/or deployed.

For demonstrative embodiments, and as a non-limiting example, a generally continuous production system is shown, and a generally continuous production method was described. However, other suitable production systems and/or production methods may be used in accordance with some embodiments; for example, a batch process in which the melt of the polymeric foam is coated with (or onto, or beneath) the back side of the flexible solar cells.

Some embodiments may provide one or more of the following a strip or sheet or array or matrix of PV solar cells, having a backing layer or a backing substrate comprising: (A) a full or at least a partial backing layer of a polymeric foam or of foamed polymer(s), and particularly a backing layer of flexible and rollable foamed polymer; that is integrally and non-detachably attached to (B) a flexible and rollable and non-brittle sheet or strip or array or matrix of solar cells. The backing layer and the flexible solar cells sheet are attached together, and are generally non-detachable from each other. In some embodiments, each of the solar cells is, by itself, a flexible and rollable and non-brittle solar cell; such as, by being singulated or grooved or trenched, having non-transcending gaps or craters that penetrate between 50 to 99.9 percent of the depth (or height) of the semiconductor wafer or the semiconductor substrate, leaving a thin layer of semiconductor wafer or the semiconductor substrate that runs beneath all those solar cells. In some embodiments, the foamed polymeric backing layer is attached to a back side (e.g., the “dark side”, or the non-active side) of the flexible solar cells sheet. In some embodiments, optionally, the polymeric foam is fortified or reinforced, such as with fibers or fillers, to provide an increased support to the solar cells.

Some embodiments provide a method and a system for producing such PV solar cells, which are flexible and rollable and non-brittle, attached to such foamed polymeric backing layer. The method may comprise, for example: producing or providing a polymer composition with a foaming agent; extruding the polymer composition to form a continuous polymeric foam melt; passing the continuous polymeric foam melt through a pair of rollers; providing a roll of flexible and rollable solar cells sheet; passing the flexible solar cells sheet through the pair of rollers, while a back side of the solar cells faces the polymeric foam melt, and causing such back side to become non-detachably attached to the polymeric foam melt, thereby creating a singular, unified, sheet of solar cells with a polymeric foam backsheet; and optionally, cooling the singular, unified, sheet (e.g., at room temperature, or by passing through or inserting into a cooling chamber of cooling sub-system). In some embodiments, the system and method may be continuous; whereas in other embodiments, they may be non-continuous and may be applied to discrete batches.

Some embodiments include a photovoltaic (PV) article comprising: a flexible and rollable and non-brittle solar cell, that is capable of being flexed and being rolled without becoming broken or non-operational, which comprises an integrated, functional, backing layer that is non-detachably attached to a back side of said flexible and rollable and non-brittle solar cell.

In some embodiments, said integrated, functional, backing layer is a sheet of foamed polymer which provides stability and mechanical support to said solar cell.

In some embodiments, said integrated, functional, backing layer is a flexible sheet of foamed polymer which provides flexibility and elasticity to said solar cell and which accompanies flexibility of said solar cell itself.

In some embodiments, said integrated, functional, backing layer comprises: (a) at least one region that is formed of foamed polymer having a first level of flexibility; which is neighboring to, (b) at least one other region that is formed of foamed polymer having a second, different, level of flexibility; wherein two or more different regions of the integrated, functional, backing layer have at least two different levels of flexibility, to provide particular and region-dependent properties of flexibility and mechanical support to said solar cell.

In some embodiments, said integrated, functional, backing layer comprises: a frame region, which surrounds a central region; wherein the frame region of the integrated, functional, backing layer is formed of foamed polymer having a first level of flexibility; wherein the central region of the integrated, functional, backing layer is formed of foamed polymer having a second, different, level of flexibility.

In some embodiments, said integrated, functional, backing layer comprises: foamed polymer that is formed exclusively of closed cells, to prevent residence of water within said foamed polymer, and/or to provide increased mechanical support to said solar cell.

In some embodiments, said integrated, functional, backing layer comprises: foamed polymer that is formed exclusively of open cells, to provide mechanical support that has increased flexibility while it supports said solar cell.

In some embodiments, said integrated, functional, backing layer comprises: (a) a first region of foamed polymer that is formed exclusively of closed cells, to prevent residence of water within said foamed polymer, and/or to provide increased mechanical support to a particular region of said solar cell, which is neighboring to: (b) a second, different, region of foamed polymer that is formed exclusively of open cells, to provide mechanical support that has increased flexibility while it supports another particular region of said solar cell.

In some embodiments, an entirety of said article, including said solar cell and including said integrated, functional, backing layer, is a singular non-detachable article that is flexible and rollable and non-brittle.

In some embodiments, the integrated, functional, backing layer that is attached to said solar cell contains, in at least one region thereof, a functional filler material having heat conducting properties or heat dissipation properties.

In some embodiments, the integrated, functional, backing layer that is attached to said solar cell contains, in at least one region thereof, a functional filler material having Ultra Violet (UV) radiation protection properties or UV radiation abruption properties.

In some embodiments, the integrated, functional, backing layer that is attached to said solar cell contains, in at least one region thereof, a fire-retardant filler material that blocks or reduces spreading of fire.

In some embodiments, the integrated, functional, backing layer that is attached to said solar cell contains, in at least one region thereof, a mechanical reinforcement material that is within said foamed polymer, and which fortifies said foamed polymer, and which is selected from the group consisting of: fibers, glass fibers, chopped glass fibers, diced glass fibers, glass fiber mats, glass fiber fabrics, polymeric fibers, chopped polymeric fibers, diced polymeric fibers, polymeric fiber mats, polymeric fiber fabrics, carbon fibers, chopped carbon fibers, diced carbon fibers, carbon fiber mats, carbon fiber fabrics, talc, mica, calcium carbonate, and a combination or mixture of two or more of said materials.

In some embodiments, the integrated, functional, backing layer that is attached to said solar cell is integrally attached beneath a backsheet of said solar cell, and provides mechanical support and buoyancy properties to said solar cell.

In some embodiments, the integrated, functional, backing layer that is attached to said solar cell which excludes any non-foamed and non-polymeric backsheet; and provides mechanical support and buoyancy properties to said solar cell.

In some embodiments, said solar cell, that is non-detachably attached to said integrated, functional, backing layer, comprises: a plurality of micro Photo Voltaic (PV) units, that have a same semiconductor wafer that integrally connects them to each other; wherein non-transcending gaps or non-transcending craters exist between each two neighboring micro PV units of said solar cell; wherein said non-transcending gaps or non-transcending craters penetrate into between 50 percent and 99.9 percent of a total depth of said semiconductor wafer; and leave a non-penetrated, singular, continuous, non-segmented, thin layer of said semiconductor wafer that is common to all said micro PV units of said solar cell; wherein said structure of non-transcending gaps or non-transcending craters, with their particular depth of non-transcending penetration into said semiconductor wafer, provide mechanical resilience properties to said solar cell and provide mechanical forces absorption properties and enable said solar cell to be flexible and rollable and non-brittle.

Some embodiments include a method of producing the PV article, the method comprising: (a) providing a polymer composition which includes at least one polymeric foaming agent; (b) providing a flexible and rollable and non-brittle sheet of solar cells; (c) extruding the polymer composition via an extruder unit, directly beneath or directly adjacent to a rear-side of the flexible and rollable and non-brittle sheet of solar cells, to form a continuous polymeric foam melt that is directly attached to said rear-side of the flexible and rollable and non-brittle sheet of solar cells immediately upon extrusion of the polymer composition from said extruder unit; (d) causing (i) the continuous polymeric foam melt, and (ii) the flexible and rollable and non-brittle sheet of solar cells, to pass together through a thin gap between two rotating rollers, while a back-side of the solar cells is adjacent to the continuous polymeric foam melt; to form a singular, unified, sheet of solar cells with a polymeric foam backing layer.

Some embodiments include a system for producing the PV article, the system comprising: (a) a first unit for providing a polymer composition which includes at least one polymeric foaming agent; (b) a second unit for providing a flexible and rollable and non-brittle sheet of solar cells; (c) an extruder unit to extrude the polymer composition directly beneath or directly adjacent to a rear-side of the flexible and rollable and non-brittle sheet of solar cells, and to output a continuous polymeric foam melt that is directly attached to said rear-side of the flexible and rollable and non-brittle sheet of solar cells immediately upon extrusion of the polymer composition from said extruder unit; (d) a third unit for causing (i) the continuous polymeric foam melt, and (ii) the flexible and rollable and non-brittle sheet of solar cells, to pass together through a thin gap between two rotating rollers, while a back-side of the solar cells is adjacent to the continuous polymeric foam melt; to form a singular, unified, sheet of solar cells with a polymeric foam backing layer.

### Additional/Optional Features:

In some embodiments, a solar cell that is utilized in conjunction with foamed polymeric backing layer or backing substrate as a singular unified structure, may be an independently (by itself) flexible and/or independently (by itself) rollable and/or independently (by itself) foldable and/or non-brittle solar cell; that does not break and does not brittle when flexed or curved or bent or folded or rolled; and that is resilient to mechanical forces and shocks; and that can autonomously absorb and/or dissipate and/or withstand mechanical forces and mechanical shocks; for example, by being segmented or singulated or grooved or trenched with non-transcending gaps or “blind gaps” or craters or grooves or trenches, that penetrate some—but not all—of the thickness (or the depth) of a silicon layer or a semiconductor body or a semiconductor wafer of such solar cell; for example, penetrating between 50 to 99.9 percent of such thickness or depth; and optionally by having filler material(s) in such grooves or trenches or non-transcending gaps or non-transcending craters, to further absorb and/or dissipate mechanical forces and shocks.

Optionally, some embodiments may be utilized in conjunction with PV devices and/or solar panels and/or components and/or methods that are described in U.S. Pat. No. 11,081,606, titled “Flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478, which is hereby incorporated by reference in its entirety; and/or with solar panels or solar cells or PV devices that are singulated or segmented or trenched or grooved, or that are flexible and/or rollable and/or foldable, and/or that include “blind gaps” or non-transcending gaps or craters.

Some embodiments may provide or may utilize a flexible and rollable and non-brittle PV cell or solar cell; wherein a silicon body or semiconductor body or semiconductor substrate or semiconductor wafer thereof has non-transcending craters or “blind gaps” that penetrate into between 75 to 99 percent (or, in some implementations, between 80 to 99 percent; or, in some implementations, between 90 to 99 percent) of a total thickness of the semiconductor body (or wafer, or substrate), and that do not penetrate into an entirety of the total thickness of sch semiconductor body (or wafer, or substrate). Such non-transcending craters or “blind gaps” operate to increase flexibility/or and mechanical resilience and/or mechanical shock absorption of the PV cell, and/or provide or increase a capability to be rollable into a roll and/or to be foldable and/or non-brittle. In some embodiments, some, or most, or all, of the non-transcending craters or “blind gaps” contain filler material(s), which may fill some or most or all of the volume thereof, wherein such filler material(s) have mechanical force absorption properties, which provide mechanical shock absorption properties and/or mechanical force dissipation properties to the PV cell.

In some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film. In some embodiments, other than the thin layer of semiconductor substrate or semiconductor wafer, that remains beneath such non-transcending gaps or craters, the solar cell is free-standing and is carrier-less and does not need to be mounted on or carried by any support layer or mounting structure.

In some embodiments, each single solar cell that is flexible and rollable by itself, is not a collection and is not an arrangement and is not an assembly of multiple discrete solar cells of PV modules, that each one of them is generally brittle/non-flexible/non-rollable and has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrode arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may. Similarly, repeated use of the phrase “in some embodiments” does not necessarily refer to the same set or group of embodiments, although it may.

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. A photovoltaic article comprising:
a flexible and rollable and non-brittle solar cell, that is capable of being flexed and being rolled without becoming broken or non-operational,
which comprises an integrated, functional, backing layer that is non-detachably attached to a back side of said flexible and rollable and non-brittle solar cell.

2. The photovoltaic article of claim 1,
wherein said integrated, functional, backing layer is a sheet of foamed polymer which provides stability and mechanical support to said solar cell.

3. The photovoltaic article of claim 1,
wherein said integrated, functional, backing layer is a flexible sheet of foamed polymer which provides flexibility and elasticity to said solar cell and which accompanies flexibility of said solar cell itself.

4. The photovoltaic article of claim 1,
wherein said integrated, functional, backing layer comprises:
(a) at least one region that is formed of foamed polymer having a first level of flexibility; which is neighboring to,
(b) at least one other region that is formed of foamed polymer having a second, different, level of flexibility;
wherein two or more different regions of the integrated, functional, backing layer have at least two different levels of flexibility, to provide particular and region-dependent properties of flexibility and mechanical support to said solar cell.

5. The photovoltaic article of claim 1,
wherein said integrated, functional, backing layer comprises:
a frame region, which surrounds a central region;
wherein the frame region of the integrated, functional, backing layer is formed of foamed polymer having a first level of flexibility;
wherein the central region of the integrated, functional, backing layer is formed of foamed polymer having a second, different, level of flexibility.

6. The photovoltaic article of claim 1,
wherein said integrated, functional, backing layer comprises:
foamed polymer that is formed exclusively of closed cells, to prevent residence of water within said foamed polymer, and/or to provide increased mechanical support to said solar cell.

7. The photovoltaic article of claim 1,
wherein said integrated, functional, backing layer comprises:
foamed polymer that is formed exclusively of open cells, to provide mechanical support that has increased flexibility while it supports said solar cell.

8. The photovoltaic article of claim 1,
wherein said integrated, functional, backing layer comprises:
(a) a first region of foamed polymer that is formed exclusively of closed cells, to prevent residence of water within said foamed polymer, and/or to provide increased mechanical support to a particular region of said solar cell,
which is neighboring to:
(b) a second, different, region of foamed polymer that is formed exclusively of open cells, to provide mechanical support that has increased flexibility while it supports another particular region of said solar cell.

9. The photovoltaic article of claim 1,
wherein an entirety of said photovoltaic article, including said solar cell and including said integrated, functional, backing layer, is a singular non-detachable article that is flexible and rollable and non-brittle.

10. The photovoltaic article of claim 1,
wherein the integrated, functional, backing layer that is attached to said solar cell contains, in at least one region thereof, a functional filler material having heat conducting properties or heat dissipation properties.

11. The photovoltaic article of claim 1,
wherein the integrated, functional, backing layer that is attached to said solar cell contains, in at least one region thereof, a functional filler material having UltraViolet (UV) radiation protection properties or UV radiation abruption properties.

12. The photovoltaic article of claim 1,
wherein the integrated, functional, backing layer that is attached to said solar cell contains, in at least one region thereof, a fire-retardant filler material that blocks or reduces spreading of fire.

13. The photovoltaic article of claim 1,
wherein the integrated, functional, backing layer that is attached to said solar cell contains, in at least one region thereof, a mechanical reinforcement material that is within said foamed polymer, and which fortifies said foamed polymer, and which is selected from the group consisting of: fibers, glass fibers, chopped glass fibers, diced glass fibers, glass fiber mats, glass fiber fabrics, polymeric fibers, chopped polymeric fibers, diced polymeric fibers, polymeric fiber mats, polymeric fiber fabrics, carbon fibers, chopped carbon fibers, diced carbon fibers, carbon fiber mats, carbon fiber fabrics, talc, mica, calcium carbonate, and a combination or mixture of two or more of said materials.

14. The photovoltaic article of claim 1,
wherein the integrated, functional, backing layer that is attached to said solar cell is integrally attached beneath a backsheet of said solar cell, and provides mechanical support and buoyancy properties to said solar cell.

15. The photovoltaic article of claim 1,
wherein the integrated, functional, backing layer that is attached to said solar cell which excludes any non-foamed and non-polymeric backsheet; and provides mechanical support and buoyancy properties to said solar cell.

16. The photovoltaic article of claim 1,
wherein said solar cell, that is non-detachably attached to said integrated, functional, backing layer, comprises:
a plurality of micro photovoltaic units, that have a same semiconductor wafer that integrally connects them to each other;
wherein non-transcending gaps or non-transcending craters exist between each two neighboring micro PV units of said solar cell;
wherein said non-transcending gaps or non-transcending craters penetrate into between 50 percent and 99.9 percent of a total depth of said semiconductor wafer; and leave a non-penetrated, singular, continuous, non-segmented, thin layer of said semiconductor wafer that is common to all said micro PV units of said solar cell;
wherein said structure of non-transcending gaps or non-transcending craters, with their particular depth of non-transcending penetration into said semiconductor wafer, provide mechanical resilience properties to said solar cell and provide mechanical forces absorption properties and enable said solar cell to be flexible and rollable and non-brittle.

17. A method of producing the photovoltaic article of claim 1,
the method comprising:
(a) providing a polymer composition which includes at least one polymeric foaming agent;
(b) providing a flexible and rollable and non-brittle sheet of solar cells;
(c) extruding the polymer composition via an extruder unit, directly beneath or directly adjacent to a rear-side of the flexible and rollable and non-brittle sheet of solar cells, to form a continuous polymeric foam melt that is directly attached to said rear-side of the flexible and rollable and non-brittle sheet of solar cells immediately upon extrusion of the polymer composition from said extruder unit;
(d) causing (i) the continuous polymeric foam melt, and (ii) the flexible and rollable and non-brittle sheet of solar cells, to pass together through a thin gap between two rotating rollers, while a back-side of the solar cells is adjacent to the continuous polymeric foam melt; to form a singular, unified, sheet of solar cells with a polymeric foam backing layer.

18. The method of claim 17,
wherein said solar cell, that is non-detachably attached to said integrated, functional, backing layer, comprises:
a plurality of micro photovoltaic units, that have a same semiconductor wafer that integrally connects them to each other;
wherein non-transcending gaps or non-transcending craters exist between each two neighboring micro PV units of said solar cell;
wherein said non-transcending gaps or non-transcending craters penetrate into between 50 percent and 99.9 percent of a total depth of said semiconductor wafer; and leave a non-penetrated, singular, continuous, non-segmented, thin layer of said semiconductor wafer that is common to all said micro PV units of said solar cell;
wherein said structure of non-transcending gaps or non-transcending craters, with their particular depth of non-transcending penetration into said semiconductor wafer, provide mechanical resilience properties to said solar cell and provide mechanical forces absorption properties, and enable said solar cell to be flexible and rollable and non-brittle.

19. A system for producing the photovoltaic article of claim 1,
the system comprising:
(a) a first unit for providing a polymer composition which includes at least one polymeric foaming agent;
(b) a second unit for providing a flexible and rollable and non-brittle sheet of solar cells;
(c) an extruder unit to extrude the polymer composition directly beneath or directly adjacent to a rear-side of the flexible and rollable and non-brittle sheet of solar cells, and to output a continuous polymeric foam melt that is directly attached to said rear-side of the flexible and rollable and non-brittle sheet of solar cells immediately upon extrusion of the polymer composition from said extruder unit;
(d) a third unit for causing (i) the continuous polymeric foam melt, and (ii) the flexible and rollable and non-brittle sheet of solar cells, to pass together through a thin gap between two rotating rollers, while a back-side of the solar cells is adjacent to the continuous polymeric foam melt; to form a singular, unified, sheet of solar cells with a polymeric foam backing layer.

20. The system of claim 19,
wherein said solar cell, that is non-detachably attached to said integrated, functional, backing layer, comprises:
a plurality of micro photovoltaic units, that have a same semiconductor wafer that integrally connects them to each other;
wherein non-transcending gaps or non-transcending craters exist between each two neighboring micro PV units of said solar cell;
wherein said non-transcending gaps or non-transcending craters penetrate into between 50 percent and 99.9 percent of a total depth of said semiconductor wafer; and leave a non-penetrated, singular, continuous, non-segmented, thin layer of said semiconductor wafer that is common to all said micro PV units of said solar cell;
wherein said structure of non-transcending gaps or non-transcending craters, with their particular depth of non-transcending penetration into said semiconductor wafer, provide mechanical resilience properties to said solar cell and provide mechanical forces absorption properties, and enable said solar cell to be flexible and rollable and non-brittle.
